(19) United States
(12) Patent Application Publication
(10) Pub. No.: US 2026/0072361 A1
(43) Pub. Date: Mar. 12, 2026

(54) MOVING APPARATUS ALONG MULTIPLE AXES

(71) Applicant: NOVA LTD, REHOVOT (IL)

(72) Inventors: Daniel EKELTCHIK, REHOVOT (IL); Slava MACHNOVSKY, REHOVOT (IL); Leonid GANNEL, REHOVOT (IL); Kobi SHUKRUN, REHOVOT (IL); Anat FRADKIN, REHOVOT (IL)

(21) Appl. No.: 18/872,867

(22) PCT Filed: Dec. 29, 2022
(86) PCT No.: PCT/IB2022/062888

§ 371 Date: Dec. 9, 2024

Related U.S. Application Data
(60) Provisional application No. 63/367,043, filed on Jun. 26, 2022.

(51) Int. Cl. G03F 7/00

(52) U.S. Cl. CPC G03F 7/706845; G03F 7/7065

(57) ABSTRACT

Positioning apparatus by determining multiple candidate paths for positioning the apparatus at multiple locations, where the positioning requires moving the apparatus in a sequence of movements along multiple axes, selecting a shortest one of the candidate paths requiring a total amount of movement of the apparatus along a selected one of the axes that is less than a total amount of movement of the apparatus required along a specified other of the axes, and causing the apparatus to traverse the selected path.

### BACKGROUND

The manufacture of semiconductor devices is heavily reliant on metrology to ensure that semiconductor devices meet design specifications. Unfortunately, as semiconductor devices become increasingly complex, and as their structural elements become increasingly small, the devices that are used to perform measurements on semiconductor devices are increasingly impacted by heat and other conditions that negatively affect their operation.

### SUMMARY

In one aspect of the invention a method is provided for positioning apparatus, the method including determining a plurality of candidate paths for positioning apparatus at a plurality of locations, where the positioning requires moving the apparatus in a sequence of movements along a plurality of axes, selecting a shortest one of the candidate paths requiring a total amount of movement of the apparatus along a selected one of the plurality of axes that is less than a total amount of movement of the apparatus required along a specified other of the plurality of axes, and causing the apparatus to traverse the selected path.

In another aspect of the invention the selecting includes selecting where the total amount of movement of the apparatus required by the selected candidate path along the selected axis is less than a predefined percentage of the total amount of movement of the apparatus required along the specified other axis.

In another aspect of the invention the selecting includes selecting where the selected candidate path substantially achieves a predefined ratio of movement of the apparatus along the selected axis with respect to the specified other axis.

In another aspect of the invention the determining, selecting, and causing are performed in support of manufacturing semiconductor devices.

In another aspect of the invention the determining includes determining the candidate paths for positioning the apparatus positioning in propinquity to each of a plurality of dies on a semiconductor wafer.

In another aspect of the invention the apparatus is mounted on a carriage that is movable along the plurality of axes.

In another aspect of the invention movement of the apparatus is effected by a plurality of motors, where each of the plurality of motors controls movement of the apparatus along a different one of the axes.

In another aspect of the invention the causing includes causing the apparatus to move along at least one selected axis using lower acceleration than used for any of the other axes.

In another aspect of the invention the causing includes causing the apparatus to move along at least one selected axis using slower kinematics than used for any of the other axes.

In another aspect of the invention the plurality of axes include X and Y axes.

In another aspect of the invention movement of the apparatus is effected by a plurality of motors that move the apparatus along the plurality of axes, each of the plurality of motors controls movement of the apparatus along a different one of the axes, and heat flux from one of the plurality of motors that moves the apparatus along the at least one selected axis negatively impacts operation of the apparatus more than any of the other motors for equal movement of the apparatus along any of the other axes.

In another aspect of the invention the apparatus includes optical metrology apparatus. In another aspect of the invention the apparatus includes metrology apparatus that is configured for use between two processing steps of a semiconductor manufacturing process. In another aspect of the invention a system is provided for positioning apparatus, the system including a path manager configured to determine a plurality of candidate paths for positioning apparatus at a plurality of locations, where the positioning requires moving the apparatus in a sequence of movements along a plurality of axes, and select a shortest one of the candidate paths requiring a total amount of movement of the apparatus along a selected one of the plurality of axes that is less than a total amount of movement of the apparatus required along a specified other of the plurality of axes, and a controller configured to cause the apparatus to traverse the selected path.

In another aspect of the invention the total amount of movement of the apparatus required along the selected axis by the selected candidate path is less than a predefined percentage of the total amount of movement of the apparatus required along the specified other axis.

In another aspect of the invention the selected candidate path substantially achieves a predefined ratio of movement of the apparatus along the selected axis with respect to the specified other axis.

In another aspect of the invention the path manager is configured to determine the candidate paths for positioning the apparatus positioning in propinquity to each of a plurality of dies on a semiconductor wafer.

In another aspect of the invention the controller is configured to cause the apparatus to move along at least one selected axis using lower acceleration than used for any of the other axes.

In another aspect of the invention the controller is configured to cause the apparatus to move along at least one selected axis using slower kinematics than used for any of the other axes.

### BRIEF DESCRIPTION OF THE DRAWINGS

Aspects of the invention will be understood and appreciated more fully from the following detailed description taken in conjunction with the appended drawings in which:

FIG. 1 is a simplified conceptual illustration of a system for moving apparatus along multiple axes, constructed and operative in accordance with an embodiment of the invention;

FIG. 2 is a simplified flowchart illustration of an exemplary method of operation of the system of FIG. 1, operative in accordance with an embodiment of the invention;

FIGS. 3A and 3B are graphs illustrating experimental data gathered during operation of the system of FIG. 1; and

FIG. 4 is a simplified block diagram illustration of an exemplary computing system for implementing one or more aspects of the invention.

### DETAILED DESCRIPTION

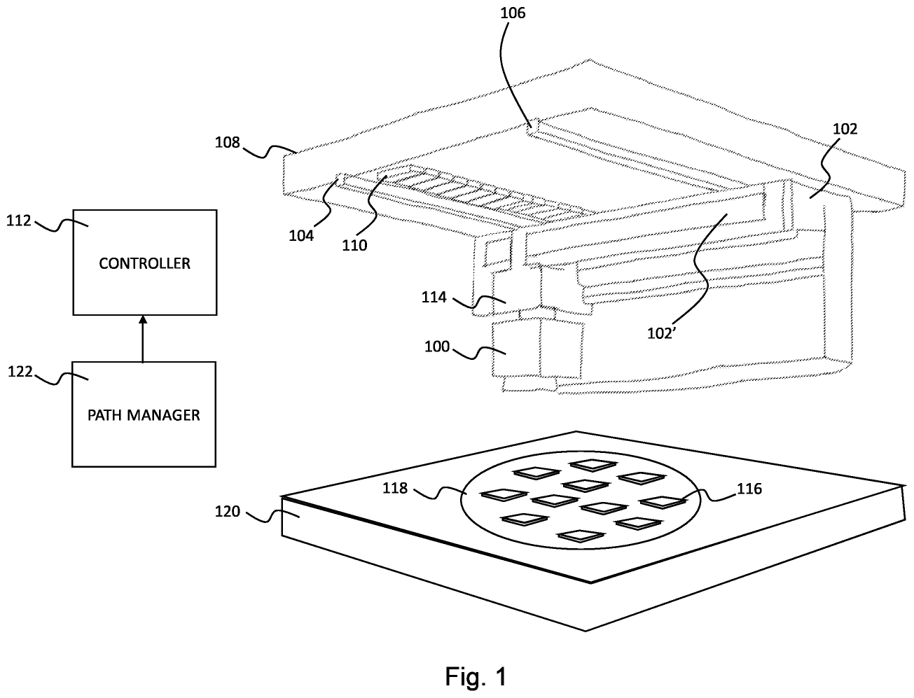

Reference is now made to FIG. 1, which is a simplified conceptual illustration of a system for moving apparatus along multiple axes, constructed and operative in accordance with an embodiment of the invention. In the system of FIG. 1, apparatus 100 is suspended from a gantry 102 that preferably includes a motor 102′that is integrated into the body of gantry 102. Gantry 102 is configured, in accordance with conventional techniques, to move apparatus 100 along an axis, such as an X axis defined along the length of gantry 102. Gantry 102 is itself suspended by rails 104 and 106 that are attached to a mount 108. A motor 110 is configured, in accordance with conventional techniques, to move apparatus 100 along an axis, such as a Y axis defined along the length of rails 104 and 106, by moving gantry 102 along rails 104 and 106. The movement of apparatus 100 along the X and Y axes as described above is preferably controlled by a controller 112 that actuates motor 102′and motor 110 to move apparatus 100. In one embodiment apparatus 100 is borne by a carriage 114, where movement of apparatus 100 as described herein is effected by movement of carriage 114, and where references herein to the movement of apparatus 100 thus refer interchangeably to the movement of carriage 114.

In one embodiment the system of FIG. 1 is used in manufacturing semiconductor devices, where apparatus 100 includes conventional metrology apparatus, such as optical metrology apparatus, for performing measurements of multiple dies 116 of a semiconductor wafer 118, such as may be mounted on a stage 120. In this scenario, apparatus 100 is moved along a predefined path traversing multiple dies 116 of semiconductor wafer 118, and preferably where each of the dies 116 are visited only once by apparatus 100, where apparatus 100 is moved to one or more predefined positions relative to each of dies 116 as needed to perform measurements of each die 116. In one embodiment apparatus 100 is configured for use between various processing steps of a semiconductor manufacturing process, such as between an etching step and chemical-mechanical polishing (CMP) step.

During operation of the system of FIG. 1 it was discovered that heat flux from the motor that moves apparatus 100 along the Y axis negatively impacts the operation of apparatus 100 more than heat flux from the motor that moves apparatus 100 along the X axis. Where apparatus 100 includes optical metrology apparatus, this heat flux was determined to deform carriage 114, causing navigational alignment errors when positioning apparatus 100 to locations necessary for performing measurements of each die 116, as well as shifting the optical path of apparatus 100 and thereby causing measurement errors. It was discovered that these errors may be reduced or eliminated by minimizing movement of apparatus 100 along the Y axis relative to movement of apparatus 100 along the X axis.

Thus, in accordance with an embodiment of the invention, the system of FIG. 1 includes a path manager 122 configured to calculate one or more candidate paths for any given configuration of dies 116 on semiconductor wafer 118, such as by employing known algorithms that address the Traveling Salesman Problem, where each of the candidate paths is configured for positioning apparatus 100 at multiple locations corresponding to the locations of the various dies 116 by moving apparatus 100 in a sequence of movements along multiple axes as described above, preferably such that each of the dies 116 are visited only once by apparatus 100. Additionally or alternatively, path manager 122 is configured to receive one or more candidate paths that are manually defined by a human operator. Path manager 122 is further configured to select a shortest one of the candidate paths that requires a total amount of movement of apparatus 100 along a selected axis that is less than a predefined percentage of a total amount of movement of apparatus 100 required along a specified other axis. Thus, for example, where it is known that heat flux from the motor that moves apparatus 100 along the Y axis negatively impacts the operation of apparatus 100 more than heat flux from the motor that moves apparatus 100 along the X axis, path manager 122 may be configured to select the shortest candidate path that requires a total movement of apparatus 100 along the Y axis that is less than 60% of the total amount of movement required of apparatus 100 along the X axis. Alternatively, path manager 122 is further configured to select a shortest one of the candidate paths that substantially achieves a predefined ratio of movement of the apparatus along a selected axis with respect to a specified other axis. Thus, for example, where it is known that heat flux from the motor that moves apparatus 100 along the Y axis negatively impacts the operation of apparatus 100 more than heat flux from the motor that moves apparatus 100 along the X axis, path manager 122 may be configured to select the shortest candidate path that substantially achieves a ratio of 2:1 of movement of the apparatus along the X axis with respect to the Y axis. The predefined percentage or ratio may be determined through experimentation by observing actual movements of apparatus 100 along various paths, where different percentages or ratios result in different navigational alignment error values and measurement error values, and where a given percentage or ratio is chosen to achieve desired maximum error values. Path manager 122 then instructs controller 112 to cause apparatus 100 to traverse the selected path.

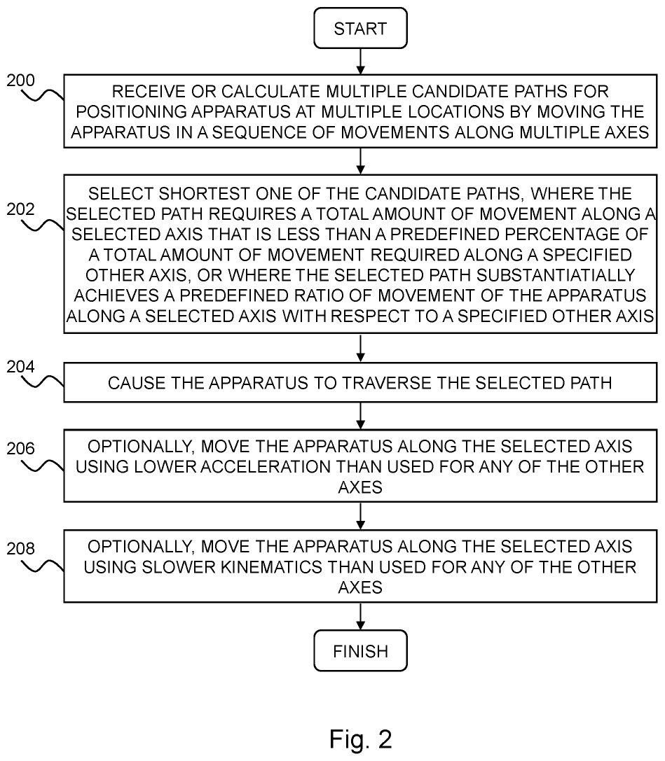

Reference is now made to FIG. 2, which is a simplified flowchart illustration of an exemplary method of operation of the system of FIG. 1, operative in accordance with an embodiment of the invention. In the method of FIG. 2, multiple candidate paths are determined for positioning apparatus at multiple locations by moving the apparatus in a sequence of movements along multiple axes (step 200). A shortest one of the candidate paths is selected, where the selected path requires a total amount of movement of the apparatus along a selected axis that is less than a predefined percentage of a total amount of movement of the apparatus required along a specified other axis, or where the selected path substantially achieves a predefined ratio of movement of the apparatus along a selected axis with respect to a specified other axis (step 202). The apparatus is then caused to traverse the selected path (step 204). Optionally, the apparatus is moved along the selected axis using lower acceleration than used for any other axes (step 206). Optionally, the apparatus is moved along the selected axis using slower kinematics than used for any other axes (step 208).

It is appreciated that the system of FIG. 1 and method of FIG. 2 may be implemented by various metrology systems, such as by Nova i500®, Nova i550®, and Nova i570® commercially available from Nova Ltd of Rehovot, Israel. It is further appreciated that the system of FIG. 1 and method of FIG. 2 are applicable to other configurations of the elements of FIG. 1 than are shown by way of example in FIG. 1.

Aspects of the system of FIG. 1 and method of FIG. 2 may be implemented in accordance with conventional techniques in computer hardware and/or in computer software embodied in a non-transitory, computer-readable medium.

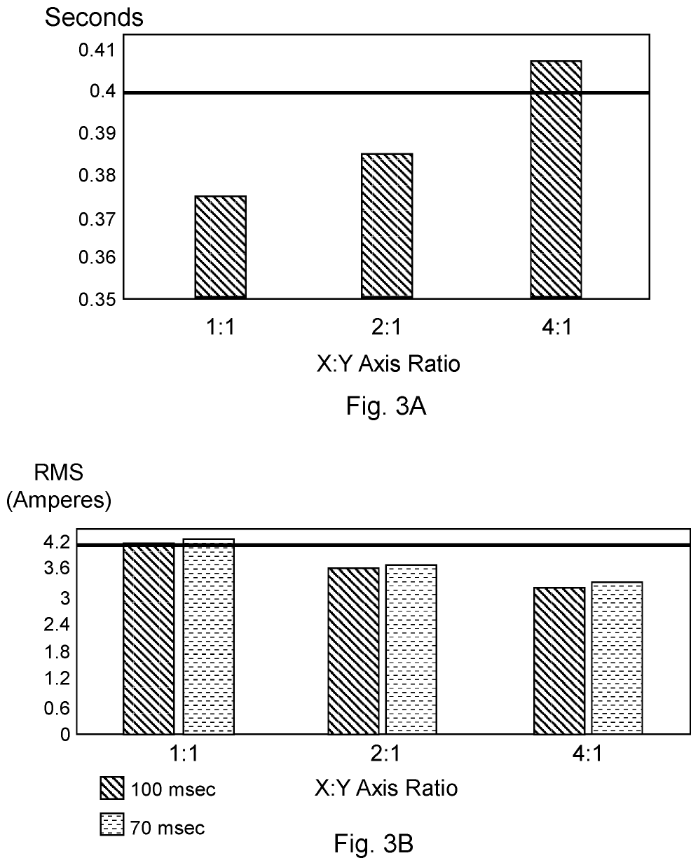

Reference is now made to FIGS. 3A and 3B, which are graphs that illustrate, based on experimental data gathered during operation of the system of FIG. 1, various types of measurements that may be considered when determining a desired ratio of movement of apparatus 100 along the X axis relative to movement of apparatus 100 along the Y axis. FIG. 3A shows the effect of different X axis to Y axis movement ratios on the average time required to move apparatus 100 between predefined locations, where a maximum time of 0.4 seconds is set, such as by a system operator to achieve a desired throughput. FIG. 3A shows that ratios of 1:1 and 1:2 are below the maximum, whereas a ratio of 1:4 is above the maximum. FIG. 3B shows the effect of different X axis to Y axis movement ratios on the root mean square (RMS) value of alternating electrical current required to move apparatus 100 along the Y axis for different time intervals, where a maximum RMS of 4.2 amperes is set, such as by a system operator to enforce known equipment operational limits, where it is known that restricting the RMS limits heat flux, up to predetermined acceptable working temperatures, from the motor that moves apparatus 100 along the Y axis. FIG. 3B shows that ratios of 1:2 and 1:4 are below the maximum, whereas a ratio of 1:1 is at or beyond the maximum. Thus, when considering both graphs, a ratio of 2:1 may be selected as being below both maxima.

Aspects of the invention are described herein with reference to flowchart illustrations and/or block diagrams of methods, apparatus (systems), and computer program products (CPP) according to embodiments of the invention. It will be understood that each block of the flowchart illustrations and/or block diagrams, and combinations of blocks in the flowchart illustrations and/or block diagrams, can be implemented by computer readable program instructions. These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

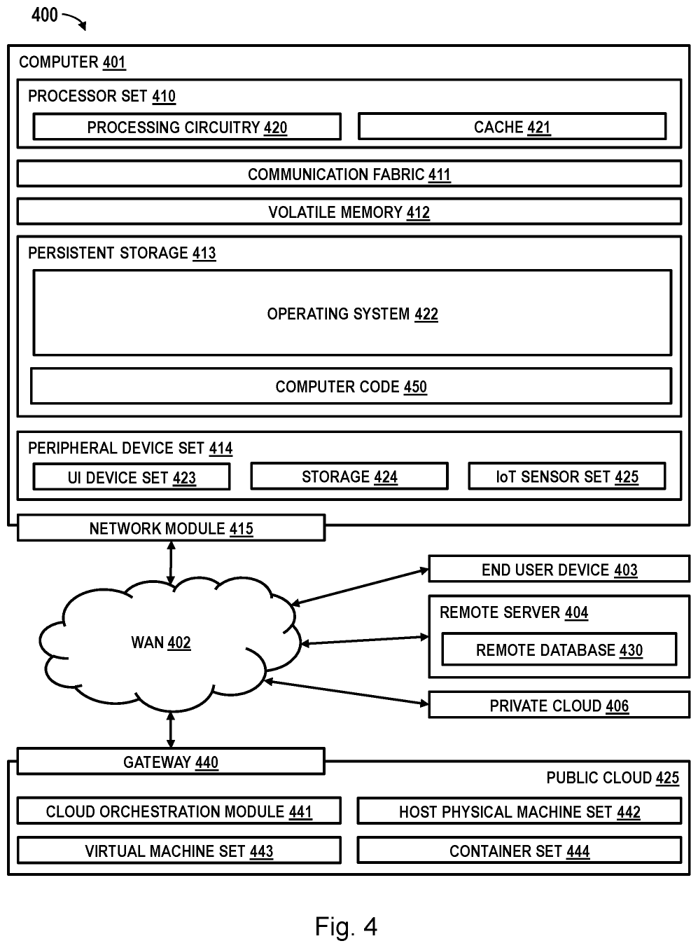

FIG. 4 illustrates an exemplary computing environment 400 for the execution of any computer code 450 configured to implement any aspect of the invention described herein. Computing environment 400 includes, for example, computer 401, wide area network (WAN) 402, end user device (EUD) 403, remote server 404, public cloud 405, and private cloud 406. In this embodiment, computer 401 includes processor set 410 (including processing circuitry 420 and cache 421), communication fabric 411, volatile memory 412, persistent storage 413 (including operating system 422 and computer code 450, as identified above), peripheral device set 414 (including user interface (UI) device set 423, storage 424, and Internet of Things (IOT) sensor set 425), and network module 415. Remote server 404 includes remote database 430. Public cloud 405 includes gateway 440, cloud orchestration module 441, host physical machine set 442, virtual machine set 443, and container set 444.

Computer 401 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 430. As is well understood in the art of computer technology, and depending upon the technology, performance of a computer-implemented method may be distributed among multiple computers and/or between multiple locations. On the other hand, in this presentation of computing environment 400, detailed discussion is focused on a single computer, specifically computer 401, to keep the presentation as simple as possible. Computer 401 may be located in a cloud, even though it is not shown in a cloud in FIG. 4. On the other hand, computer 401 is not required to be in a cloud except to any extent as may be affirmatively indicated.

Processor set 410 includes one, or more, computer processors of any type now known or to be developed in the future. Processing circuitry 420 may be distributed over multiple packages, for example, multiple, coordinated integrated circuit chips. Processing circuitry 420 may implement multiple processor threads and/or multiple processor cores. Cache 421 is memory that is located in the processor chip package(s) and is typically used for data or code that should be available for rapid access by the threads or cores running on processor set 410. Cache memories are typically organized into multiple levels depending upon relative proximity to the processing circuitry. Alternatively, some, or all, of the cache for the processor set may be located “off chip.” In some computing environments, processor set 410 may be designed for working with qubits and performing quantum computing.

Computer readable program instructions are typically loaded onto computer 401 to cause a series of operational steps to be performed by processor set 410 of computer 401 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 421 and the other storage media discussed below. The program instructions, and associated data, are accessed by processor set 410 to control and direct performance of the inventive methods. In computing environment 400, at least some of the instructions for performing the inventive methods may be stored in computer code 450 in persistent storage 413.

Communication fabric 411 is the signal conduction path that allows the various components of computer 401 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 412 is any type of volatile memory now known or to be developed in the future. Examples include dynamic type random access memory (RAM) or static type RAM. Typically, volatile memory 412 is characterized by random access, but this is not required unless affirmatively indicated. In computer 401, the volatile memory 412 is located in a single package and is internal to computer 401, but, alternatively or additionally, the volatile memory may be distributed over multiple packages and/or located externally with respect to computer 401.

Persistent storage 413 is any form of non-volatile storage for computers that is now known or to be developed in the future. The non-volatility of this storage means that the stored data is maintained regardless of whether power is being supplied to computer 401 and/or directly to persistent storage 413. Persistent storage 413 may be a read only memory (ROM), but typically at least a portion of the persistent storage allows writing of data, deletion of data and re-writing of data. Some familiar forms of persistent storage include magnetic disks and solid state storage devices. Operating system 422 may take several forms, such as various known proprietary operating systems or open source Portable Operating System Interface-type operating systems that employ a kernel. The code included in computer code 450 typically includes at least some of the computer code involved in performing the inventive methods.

Peripheral device set 414 includes the set of peripheral devices of computer 401. Data communication connections between the peripheral devices and the other components of computer 401 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 423 may include components such as a display screen, speaker, microphone, wearable devices (such as goggles and smart watches), keyboard, mouse, printer, touchpad, game controllers, and haptic devices. Storage 424 is external storage, such as an external hard drive, or insertable storage, such as an SD card. Storage 424 may be persistent and/or volatile. In some embodiments, storage 424 may take the form of a quantum computing storage device for storing data in the form of qubits. In embodiments where computer 401 is required to have a large amount of storage (for example, where computer 401 locally stores and manages a large database) then this storage may be provided by peripheral storage devices designed for storing very large amounts of data, such as a storage area network (SAN) that is shared by multiple, geographically distributed computers. IoT sensor set 425 is made up of sensors that can be used in Internet of Things applications. For example, one sensor may be a thermometer and another sensor may be a motion detector.

Network module 415 is the collection of computer software, hardware, and firmware that allows computer 401 to communicate with other computers through WAN 402. Network module 415 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 415 are performed on the same physical hardware device. In other embodiments (for example, embodiments that utilize software-defined networking (SDN)), the control functions and the forwarding functions of network module 415 are performed on physically separate devices, such that the control functions manage several different network hardware devices. Computer readable program instructions for performing the inventive methods can typically be downloaded to computer 401 from an external computer or external storage device through a network adapter card or network interface included in network module 415.

WAN 402 is any wide area network (for example, the internet) capable of communicating computer data over non-local distances by any technology for communicating computer data, now known or to be developed in the future. In some embodiments, the WAN 402 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 403 is any computer system that is used and controlled by an end user (for example, a customer of an enterprise that operates computer 401), and may take any of the forms discussed above in connection with computer 401. EUD 403 typically receives helpful and useful data from the operations of computer 401. For example, in a hypothetical case where computer 401 is designed to provide a recommendation to an end user, this recommendation would typically be communicated from network module 415 of computer 401 through WAN 402 to EUD 403. In this way, EUD 403 can display, or otherwise present, the recommendation to an end user. In some embodiments, EUD 403 may be a client device, such as thin client, heavy client, mainframe computer, desktop computer and so on.

Remote server 404 is any computer system that serves at least some data and/or functionality to computer 401. Remote server 404 may be controlled and used by the same entity that operates computer 401. Remote server 404 represents the machine(s) that collect and store helpful and useful data for use by other computers, such as computer 401. For example, in a hypothetical case where computer 401 is designed and programmed to provide a recommendation based on historical data, then this historical data may be provided to computer 401 from remote database 430 of remote server 404.

Public cloud 405 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 405 is performed by the computer hardware and/or software of cloud orchestration module 441. The computing resources provided by public cloud 405 are typically implemented by virtual computing environments that run on various computers making up the computers of host physical machine set 442, which is the universe of physical computers in and/or available to public cloud 405. The virtual computing environments (VCEs) typically take the form of virtual machines from virtual machine set 443 and/or containers from container set 444. It is understood that these VCEs may be stored as images and may be transferred among and between the various physical machine hosts, either as images or after instantiation of the VCE. Cloud orchestration module 441 manages the transfer and storage of images, deploys new instantiations of VCEs and manages active instantiations of VCE deployments. Gateway 440 is the collection of computer software, hardware, and firmware that allows public cloud 405 to communicate through WAN 402.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 406 is similar to public cloud 405, except that the computing resources are only available for use by a single enterprise. While private cloud 406 is depicted as being in communication with WAN 402, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 405 and private cloud 406 are both part of a larger hybrid cloud.

The descriptions of the various embodiments of the invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for positioning apparatus, the method comprising:
determining a plurality of candidate paths for positioning apparatus at a plurality of locations, wherein the positioning requires moving the apparatus in a sequence of movements along a plurality of axes;
selecting a shortest one of the candidate paths requiring a total amount of movement of the apparatus along a selected one of the plurality of axes that is less than a total amount of movement of the apparatus required along a specified other of the plurality of axes; and
causing the apparatus to traverse the selected path.

2. The method according to claim 1 wherein the selecting comprises selecting wherein the total amount of movement of the apparatus required by the selected candidate path along the selected axis is less than a predefined percentage of the total amount of movement of the apparatus required along the specified other axis.

3. The method according to claim 1 wherein the selecting comprises selecting wherein the selected candidate path substantially achieves a predefined ratio of movement of the apparatus along the selected axis with respect to the specified other axis.

4. The method according to claim 1 wherein the determining, selecting, and causing are performed in support of manufacturing semiconductor devices.

5. The method according to claim 6 wherein the determining comprises determining the candidate paths for positioning the apparatus positioning in propinquity to each of a plurality of dies on a semiconductor wafer.

6. The method according to claim 1 wherein the apparatus is mounted on a carriage that is movable along the plurality of axes.

7. The method according to claim 1 wherein movement of the apparatus is effected by a plurality of motors, wherein each of the plurality of motors controls movement of the apparatus along a different one of the axes.

8. The method according to claim 1 wherein the causing comprises causing the apparatus to move along at least one selected axis using lower acceleration than used for any of the other axes.

9. The method according to claim 1 wherein the causing comprises causing the apparatus to move along at least one selected axis using slower kinematics than used for any of the other axes.

10. The method according to claim 1 wherein the plurality of axes include X and Y axes.

11. The method according to claim 1 wherein
movement of the apparatus is effected by a plurality of motors that move the apparatus along the plurality of axes,
each of the plurality of motors controls movement of the apparatus along a different one of the axes, and
heat flux from one of the plurality of motors that moves the apparatus along the at least one selected axis negatively impacts operation of the apparatus more than any of the other motors for equal movement of the apparatus along any of the other axes.

12. The method according to claim 1 wherein the apparatus includes optical metrology apparatus.

13. The method according to claim 1 wherein the apparatus includes metrology apparatus that is configured for use between two processing steps of a semiconductor manufacturing process.

14. A system for positioning apparatus, the system comprising:
a path manager configured to
determine a plurality of candidate paths for positioning apparatus at a plurality of locations, wherein the positioning requires moving the apparatus in a sequence of movements along a plurality of axes, and
select a shortest one of the candidate paths requiring a total amount of movement of the apparatus along a selected one of the plurality of axes that is less than a total amount of movement of the apparatus required along a specified other of the plurality of axes; and
a controller configured to cause the apparatus to traverse the selected path.

15. The system according to claim 1 wherein the total amount of movement of the apparatus required along the selected axis by the selected candidate path is less than a predefined percentage of the total amount of movement of the apparatus required along the specified other axis.

16. The system according to claim 1 wherein the selected candidate path substantially achieves a predefined ratio of movement of the apparatus along the selected axis with respect to the specified other axis.

17. The system according to claim 14 wherein the path manager is configured to determine the candidate paths for positioning the apparatus positioning in propinquity to each of a plurality of dies on a semiconductor wafer.

18. The system according to claim 14 wherein the apparatus is mounted on a carriage that is movable along the plurality of axes.

19. The system according to claim 14 wherein movement of the apparatus is effected by a plurality of motors, wherein each of the plurality of motors controls movement of the apparatus along a different one of the axes.

20. The system according to claim 14 wherein the controller is configured to cause the apparatus to move along at least one selected axis using lower acceleration than used for any of the other axes.

21. The system according to claim 14 wherein the controller is configured to cause the apparatus to move along at least one selected axis using slower kinematics than used for any of the other axes.

22. The system according to claim 14 wherein the plurality of axes include X and Y axes.

23. The system according to claim 14 wherein
movement of the apparatus is effected by a plurality of motors that move the apparatus along the plurality of axes,
each of the plurality of motors controls movement of the apparatus along a different one of the axes, and
heat flux from one of the plurality of motors that moves the apparatus along the at least one selected axis negatively impacts operation of the apparatus more than any of the other motors for equal movement of the apparatus along any of the other axes.

24. The system according to claim 14 wherein the apparatus includes optical metrology apparatus.

25. The system according to claim 14 wherein the apparatus includes metrology apparatus that is configured for use between two processing steps of a semiconductor manufacturing process.
